(19) United States
(12) Patent Application Publication
(10) Pub. No.: US 2026/0223442 A1
(43) Pub. Date: Jul. 30, 2026

(54) SEMICONDUCTOR DEVICE STRUCTURE AND METHODS OF FORMING THE SAME

(71) Applicant: TAIWAN SEMICONDUCTOR MANUFACTURING COMPANY, LTD., Hsinchu (TW)

(72) Inventors: Hsueh-Yu CHEN, New Taipei (TW); Chia-Chi YU, New Taipei (TW); Wei-Qing GUO, Hsinchu (TW); Jui Fu HSIEH, Hsinchu (TW); Yi-Jen CHEN, Hsinchu (TW)

(21) Appl. No.: 19/197,997

(22) Filed: May 3, 2025

Related U.S. Application Data
(60) Provisional application No. 63/749,055, filed on Jan. 24, 2025.

(51) Int. Cl. H10D 84/83; H01L 21/3065; H10D 30/00; H10D 30/01; H10D 30/43; H10D 62/00; H10D 62/10; H10D 62/13; H10D 64/01; H10D 84/01

(52) U.S. Cl. CPC H10D 84/8312; H10D 30/014; H10D 30/0194; H10D 30/43; H10D 30/503; H10D 30/506; H10D 62/021; H10D 62/121; H10D 62/151; H10D 64/017; H10D 64/021; H10D 84/013; H10D 84/832; H10P 50/242

(57) ABSTRACT

A semiconductor device structure and methods of forming the same are described. The method includes forming a fin structure over a substrate, forming a sacrificial gate structure on a portion of the fin structure, and recessing an exposed portion of the fin structure to form a source/drain recess. The exposed portion of the fin structure is recessed by a cyclic etching process, the cyclic etching process includes performing a plurality of cycles, and each cycle includes a plasma formation stage, an etch stage, and a purge stage. A shape of the source/drain recess is controlled by adjusting a ratio of a time duration of the purge stage to a time duration of the plasma formation and etch stages.

### CROSS-REFERENCE TO RELATED APPLICATIONS

This application claims priority to U.S. Provisional Application Ser. No. 63/749,055 filed Jan. 24, 2025, which is incorporated by reference in its entirety.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling down has also increased the complexity of processing and manufacturing ICs.

Therefore, there is a need to improve processing and manufacturing ICs.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1, 2, 3, 4, and 5 are perspective views of various stages of manufacturing a semiconductor device structure, in accordance with some embodiments.

FIG. 6A is a perspective view of one of various stages of manufacturing the semiconductor device structure, in accordance with some embodiments.

FIG. 6B is a cross-sectional side view of one of various stages of manufacturing the semiconductor device structure taken along line A-A of FIG. 5, in accordance with some embodiments.

FIGS. 7A, 7B, and 7C are cross-sectional side views of various stages of manufacturing the semiconductor device structure taken along line A-A of FIG. 5, in accordance with some embodiments.

FIG. 7D is a cross-sectional side view of one of various stages of manufacturing the semiconductor device structure taken along line B-B of FIG. 5, in accordance with some embodiments.

FIGS. 8A, 8B, and 8C are cross-sectional side views of a portion of the semiconductor device structure of FIG. 7D, in accordance with some embodiments.

FIGS. 9A, 9B, and 9C are charts showing different time durations of three stages of a cyclic etching process, in accordance with some embodiments.

FIGS. 10A and 10B are cross-sectional side views of various stages of manufacturing the semiconductor device structure taken along line A-A of FIG. 5, in accordance with some embodiments.

FIGS. 11A, 11B, 12A, 12B, 13A, and 13B are cross-sectional side views showing the formation of a source/drain region, in accordance with some embodiments.

FIGS. 11A-1 and 11A-2 are cross-sectional side views of a source/drain region, in accordance with alternative embodiments.

FIG. 13C is a cross-sectional side view of the source/drain region of FIG. 13A taken along line B-B of FIG. 5, in accordance with some embodiments.

FIGS. 14A and 14B are cross-sectional side views of the source/drain region of FIG. 13A taken along lines B-B, A-A of FIG. 5, respectively, in accordance with alternative embodiments.

FIGS. 15A, 15B, 15C, and 15D are cross-sectional side views of various stages of manufacturing the semiconductor device structure taken along line B-B of FIG. 5, in accordance with some embodiments.

FIG. 16 is a cross-sectional side view of one of various stages of manufacturing the semiconductor device structure taken along line A-A of FIG. 5, in accordance with alternative embodiments.

FIG. 17 is a cross-sectional side view of one of various stages of manufacturing the semiconductor device structure taken along line A-A of FIG. 5, in accordance with alternative embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “over,” “on,” “top,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

While the embodiments of this disclosure are discussed with respect to nanostructure channel FETs, such as gate all around (GAA) FETs, for example Horizontal Gate All Around (HGAA) FETs or Vertical Gate All Around (VGAA) FETs, implementations of some aspects of the present disclosure may be used in other processes and/or in other devices, such as planar FETs, Fin-FETs, and other suitable devices. A person having ordinary skill in the art will readily understand other modifications that may be made are contemplated within the scope of this disclosure. In cases where gate all around (GAA) transistor structures are adapted, the GAA transistor structures may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

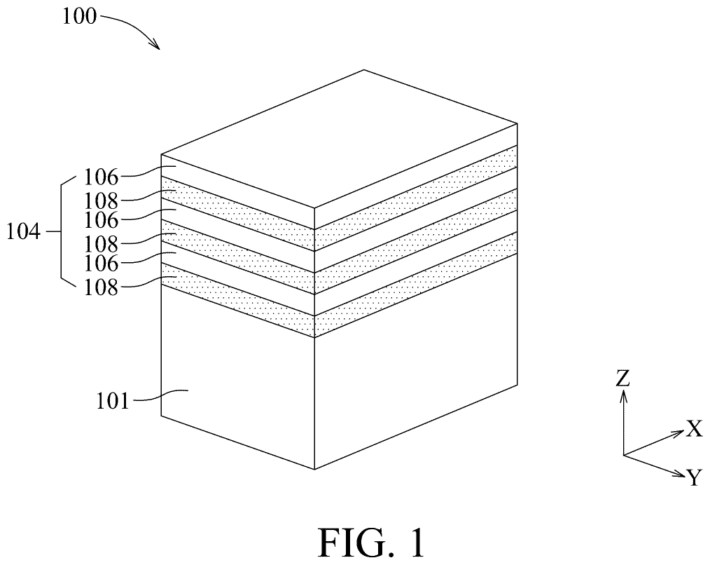

FIGS. 1-15D show exemplary processes for manufacturing a semiconductor device structure 100 according to embodiments of the present disclosure. It is understood that additional operations can be provided before, during, and after processes shown by FIGS. 1-15D, and some of the operations described below can be replaced or eliminated, for additional embodiments of the method. The order of the operations/processes is not limiting and may be interchangeable.

FIGS. 1, 2, 3, 4, and 5 are perspective views of various stages of manufacturing a semiconductor device structure 100, in accordance with some embodiments. As shown in FIG. 1, a semiconductor device structure 100 includes a stack of semiconductor layers 104 formed over a front side of a substrate 101. The substrate 101 may be a semiconductor substrate. The substrate 101 may include a crystalline semiconductor material such as, but not limited to silicon (Si), germanium (Ge), silicon germanium (SiGe), gallium arsenide (GaAs), indium antimonide (InSb), gallium phosphide (GaP), gallium antimonide (GaSb), indium aluminum arsenide (InAlAs), indium gallium arsenide (InGaAs), gallium antimony phosphide (GaSbP), gallium arsenic antimonide (GaAsSb) and indium phosphide (InP).

The substrate 101 may include various regions that have been doped with impurities (e.g., dopants having p-type or n-type conductivity). Depending on circuit design, the dopants may be, for example phosphorus for an n-type field effect transistors (NFET) and boron for a p-type field effect transistors (PFET).

The stack of semiconductor layers 104 includes alternating semiconductor layers made of different materials to facilitate formation of nanostructure channels in a multi-gate device, such as nanostructure channel FETs. In some embodiments, the stack of semiconductor layers 104 includes first semiconductor layers 106 and second semiconductor layers 108. In some embodiments, the stack of semiconductor layers 104 includes alternating first and second semiconductor layers 106, 108. The first semiconductor layers 106 and the second semiconductor layers 108 are made of semiconductor materials having different etch selectivity and/or oxidation rates. For example, the first semiconductor layers 106 may be made of Si and the second semiconductor layers 108 may be made of SiGe. In some examples, the first semiconductor layers 106 may be made of SiGe and the second semiconductor layers 108 may be made of Si. Alternatively, in some embodiments, either of the semiconductor layers 106, 108 may be or include other materials such as Ge, SiC, GaAs, GaP, InP, InAs, InSb, GaAsP, AlInAs, AlGaAs, InGaAs, GaInP, GaInAsP, or any combinations thereof.

The first and second semiconductor layers 106, 108 are formed by any suitable deposition process, such as epitaxy. By way of example, epitaxial growth of the layers of the stack of semiconductor layers 104 may be performed by a molecular beam epitaxy (MBE) process, a metalorganic chemical vapor deposition (MOCVD) process, and/or other suitable epitaxial growth processes.

The first semiconductor layers 106 or portions thereof may form nanostructure channel(s) of the semiconductor device structure 100 in later fabrication stages. The term nanostructure is used herein to designate any material portion with nanoscale, or even microscale dimensions, and having an elongate shape, regardless of the cross-sectional shape of this portion. Thus, this term designates both circular and substantially circular cross-section elongate material portions, and beam or bar-shaped material portions including, for example, a cylindrical in shape or substantially rectangular cross-section. The nanostructure channel(s) of the semiconductor device structure 100 may be surrounded by a gate electrode. The semiconductor device structure 100 may include a nanostructure transistor. The nanostructure transistors may be referred to as nanosheet transistors, nanowire transistors, gate-all-around (GAA) transistors, multi-bridge channel (MBC) transistors, or any transistors having the gate electrode surrounding the channels. The use of the first semiconductor layers 106 to define a channel or channels of the semiconductor device structure 100 is further discussed below.

Each first semiconductor layer 106 may have a thickness in a range between about 3 nm and about 30 nm. Second semiconductor layer 108 may have a thickness that is equal, less, or greater than the thickness of the first semiconductor layer 106. In some embodiments, each second semiconductor layer 108 has a thickness in a range between about 2 nm and about 50 nm. Three first semiconductor layers 106 and three second semiconductor layers 108 are alternately arranged as illustrated in FIG. 1, which is for illustrative purposes and not intended to be limiting beyond what is specifically recited in the claims. It can be appreciated that any number of first and second semiconductor layers 106, 108 can be formed in the stack of semiconductor layers 104, and the number of layers depending on the predetermined number of channels for the semiconductor device structure 100. In some embodiments, the stack of semiconductor layers 104 includes two first semiconductor layers 106. In some embodiments, the stack of semiconductor layers 104 includes three first semiconductor layers 106. In some embodiments, the stack of semiconductor layers 104 includes four first semiconductor layers 106.

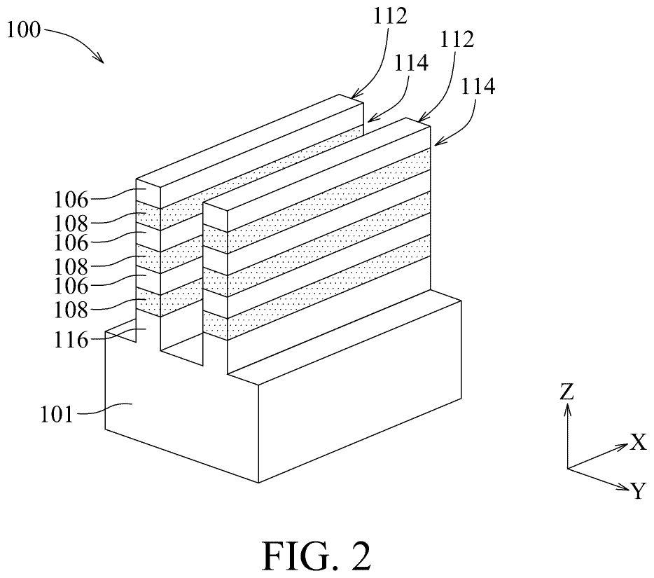

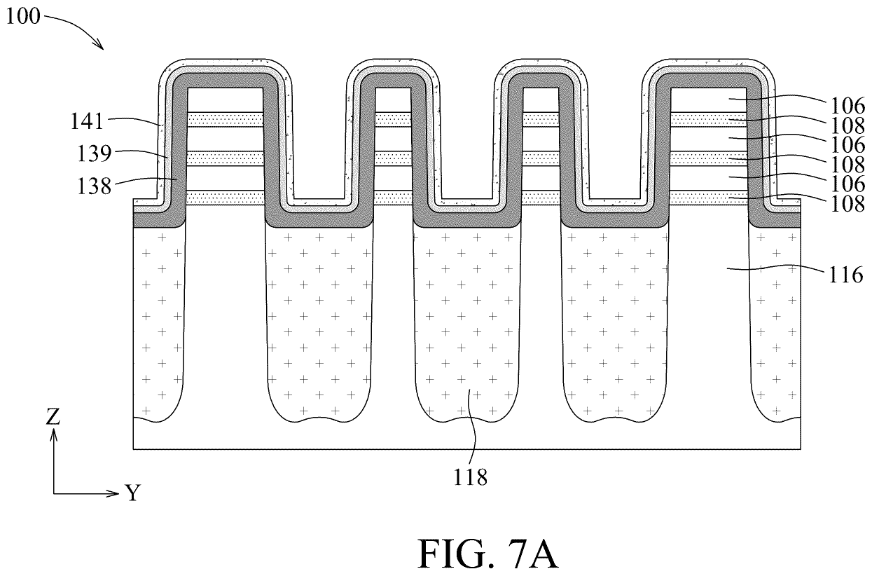

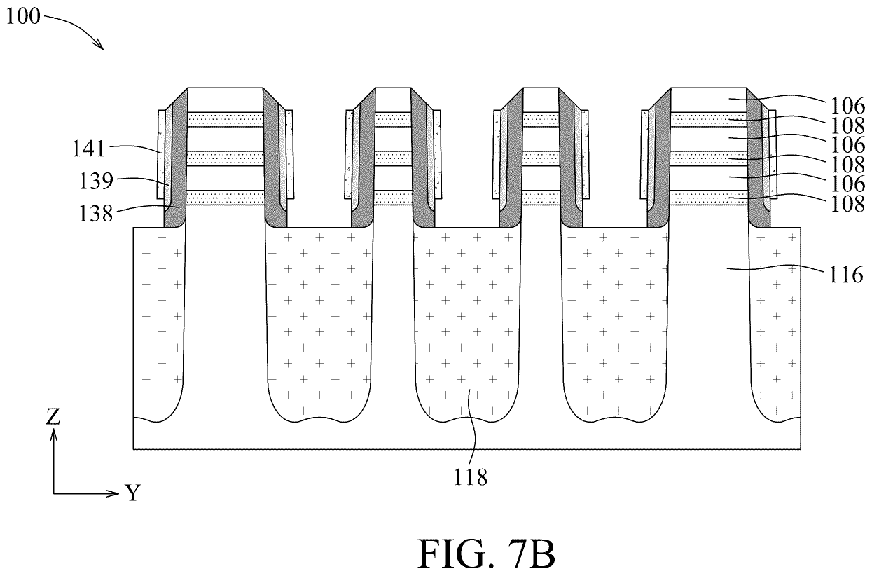

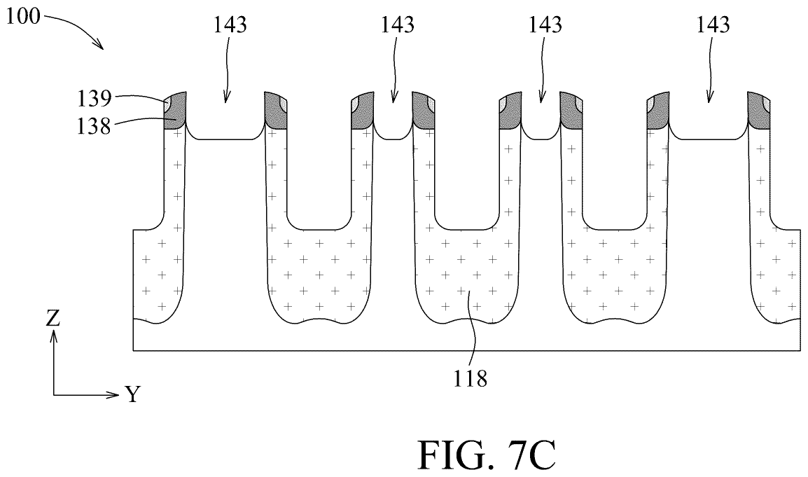

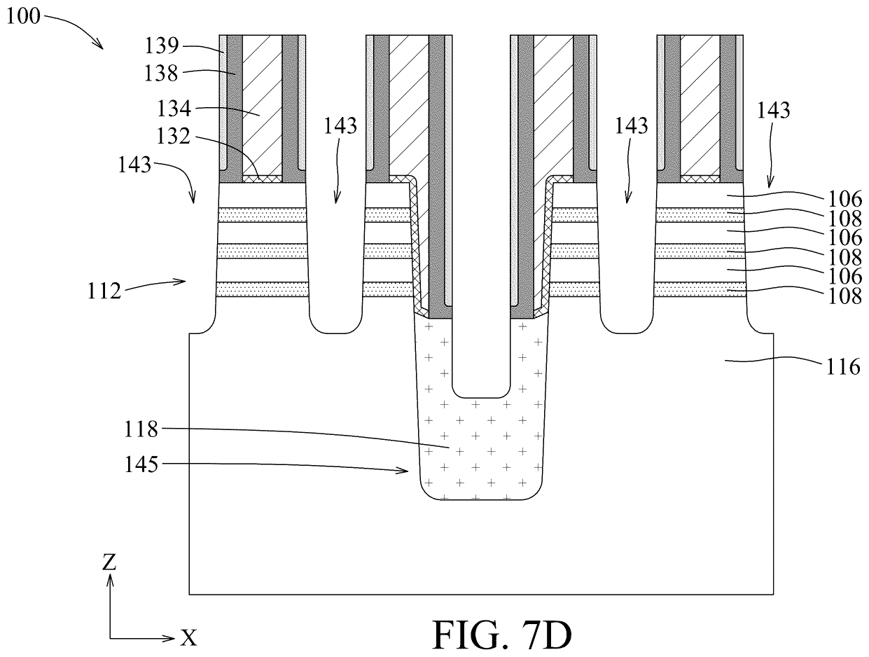

As shown in FIG. 2, fin structures 112 are formed from the stack of semiconductor layers 104. Each fin structure 112 has an upper portion including the semiconductor layers 106, 108 and a substrate portion 116 formed from the substrate 101. The fin structures 112 may be formed by patterning a hard mask layer (not shown) formed on the stack of semiconductor layers 104 using multi-patterning operations including photo-lithography and etching processes. The etching process can include dry etching, wet etching, reactive ion etching (RIE), and/or other suitable processes. The photo-lithography process may include forming a photoresist layer (not shown) over the hard mask layer, exposing the photoresist layer to a pattern, performing post-exposure bake processes, and developing the photoresist layer to form a masking element including the photoresist layer. In some embodiments, patterning the photoresist layer to form the masking element may be performed using an electron beam (e-beam) lithography process. The etching process forms trenches 114 in unprotected regions through the hard mask layer, through the stack of semiconductor layers 104, and into the substrate 101, thereby leaving the plurality of extending fin structures 112. The trenches 114 extend along the X direction. The trenches 114 may be etched using a dry etch (e.g., RIE), a wet etch, and/or combination thereof. In some embodiments, an opening 145 (FIG. 7D) may be formed in a fin structure 112 to separate the fin structure 112 into two portions.

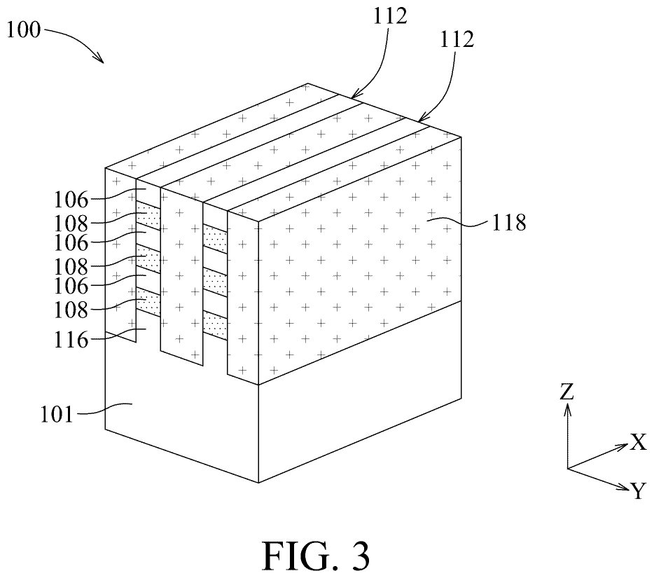

As shown in FIG. 3, after the fin structures 112 are formed, an insulating material 118 is formed on the substrate 101. The insulating material 118 fills the trenches 114 between neighboring fin structures 112 until the fin structures 112 are embedded in the insulating material 118. Then, a planarization operation, such as a chemical mechanical polishing (CMP) method and/or an etch-back method, is performed such that the top of the fin structures 112 is exposed. The insulating material 118 may be made of silicon oxide, silicon nitride, silicon oxynitride (SiON), SiOCN, SiCN, fluorine-doped silicate glass (FSG), a low-K dielectric material, or any suitable dielectric material. The insulating material 118 may be formed by any suitable method, such as low-pressure chemical vapor deposition (LPCVD), plasma enhanced CVD (PECVD) or flowable CVD (FCVD).

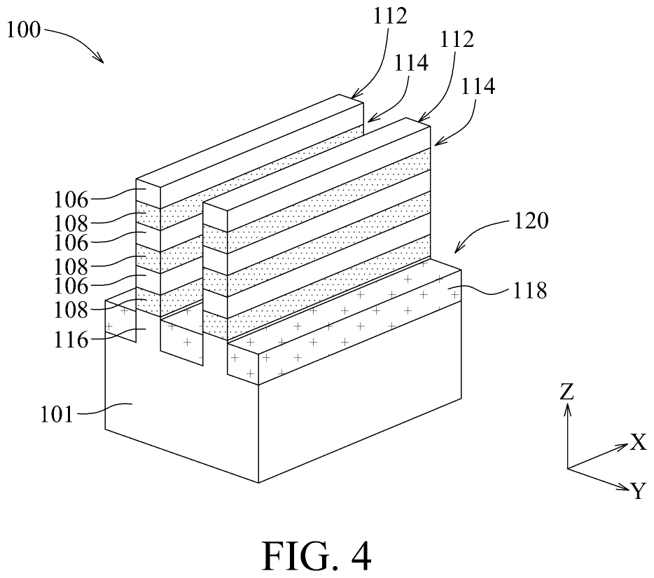

As shown in FIG. 4, the insulating material 118 is recessed to form isolation regions 120. The recess of the insulating material 118 exposes portions of the fin structures 112, such as the stack of semiconductor layers 104. The recess of the insulating material 118 reveals the trenches 114 between the neighboring fin structures 112. The isolation regions 120 may be formed using a suitable process, such as a dry etching process, a wet etching process, or a combination thereof. A top surface of the insulating material 118 may be level with or below a surface of the second semiconductor layers 108 in contact with the substrate portion 116 formed from the substrate 101. In some embodiments, the isolation regions 120 are the shallow trench isolation (STI) regions. In some embodiments, the isolation region 120 may be also formed in the opening 145 (FIG. 7D) that separates the fin structure 112 into two portions.

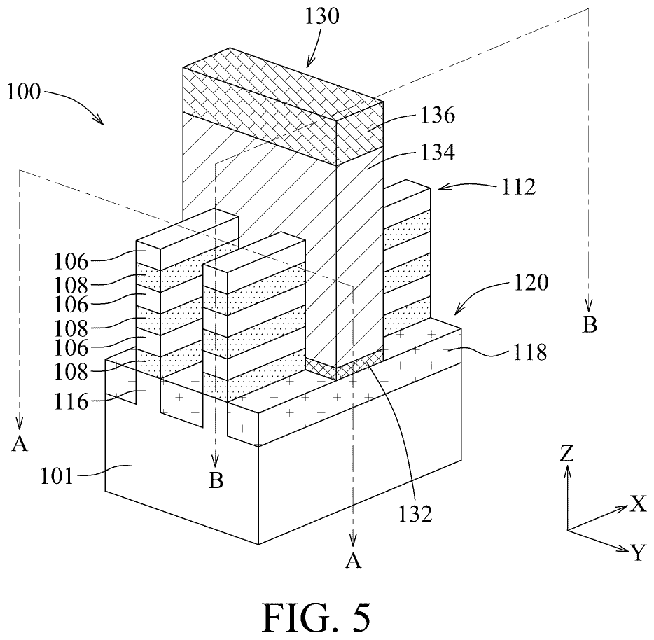

As shown in FIG. 5, one or more sacrificial gate structures 130 (only one is shown) are formed over the semiconductor device structure 100. The sacrificial gate structures 130 are formed over a portion of the fin structures 112. Each sacrificial gate structure 130 may include a sacrificial gate dielectric layer 132, a sacrificial gate electrode layer 134, and a mask layer 136. The sacrificial gate dielectric layer 132, the sacrificial gate electrode layer 134, and the mask layer 136 may be formed by sequentially depositing blanket layers of the sacrificial gate dielectric layer 132, the sacrificial gate electrode layer 134, and the mask layer 136, and then patterning those layers into the sacrificial gate structures 130. While one sacrificial gate structure 130 is shown, two or more sacrificial gate structures 130 may be arranged along the X direction in some embodiments.

The sacrificial gate dielectric layer 132 may include one or more layers of dielectric material, such as a silicon oxide-based material. The sacrificial gate electrode layer 134 may include silicon such as polycrystalline silicon or amorphous silicon. The mask layer 136 may include more than one layer, such as an oxide layer and a nitride layer. The portions of the fin structures 112 that are covered by the sacrificial gate electrode layer 134 of the sacrificial gate structure 130 serve as channel regions for the semiconductor device structure 100.

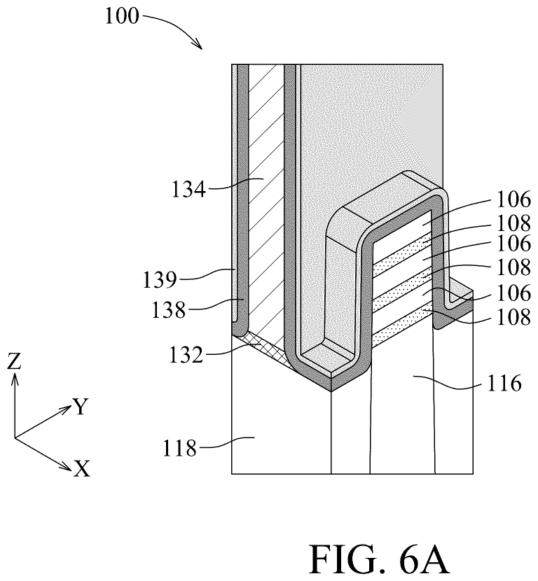

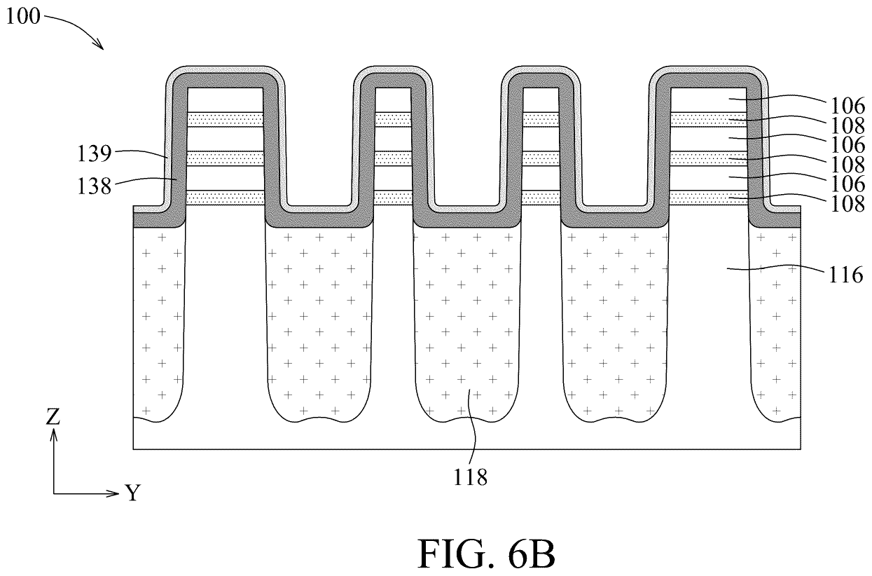

FIG. 6A is a perspective view of one of various stages of manufacturing the semiconductor device structure 100, in accordance with some embodiments. FIG. 6B is a cross-sectional side view of one of various stages of manufacturing the semiconductor device structure 100 taken along line A-A of FIG. 5, in accordance with some embodiments. FIG. 6B is a corresponding cross-sectional view of the semiconductor device structure 100 shown in FIG. 6A. As shown in FIGS. 6A and 6B, first and second spacers 138, 139 are deposited on the exposed surfaces of the semiconductor device structure 100. For example, the first spacer 138 is deposited on the fin structures 112, the isolation regions 120, and the sacrificial gate structure 130, and the second spacer 139 is deposited on the first spacer 138. The first spacer 138 may be made of a dielectric material such as silicon oxide, silicon nitride, silicon carbide, silicon oxynitride, SiCN, silicon oxycarbide, SiCON, and/or combinations thereof. The first spacer 138 may be formed by any suitable process. In some embodiments, the first spacer 138 is a conformal layer formed by a conformal process, such as an atomic layer deposition (ALD) process.

The second spacer 139 may include any suitable dielectric material, such as SiOₓ, SiON, SiN, SiCON, or SiCO. The second spacer 139 may have a thickness ranging from about 0.5 nm to about 5 nm. The second spacer 139 may be formed by any suitable process. In some embodiments, the second spacer 139 is deposited by CVD, PECVD, or electron cyclotron resonance CVD (ECR-CVD). In some embodiments, the composition of the second spacer 139 may be different from the composition of the first spacer 138. In some embodiments, a single spacer, such as the first spacer 138, is present, while the second spacer 139 is not present.

FIGS. 7A, 7B, and 7C are cross-sectional side views of various stages of manufacturing the semiconductor device structure 100 taken along line A-A of FIG. 5, in accordance with some embodiments. FIGS. 7A-7C illustrate the portions of the fin structures 112 not covered by the sacrificial gate structure 130. As shown in FIG. 7A, a protection layer 141 is deposited on the second spacer 139. The protection layer 141 may include a material different from the second spacer 139. In some embodiments, the protection layer 141 includes silicon oxide. The protection layer 141 may be formed by any suitable method. In some embodiments, the protection layer 141 may be formed by CVD, PECVD, or ALD. A silicon-containing precursor, such as SiCl₄, and an oxygen-containing precursor, such as O₂, may be used to form the protection layer 141. In some embodiments, the protection layer 141 is a conformal layer formed by ALD, as shown in FIG. 7A.

Next, as shown in FIG. 7B, an anisotropic etching process is performed to remove horizontal portions of the protection layer 141, the second spacer 139, and the first spacer 138. The anisotropic etching process may utilize an etchant that remove dielectric materials at a faster rate than semiconductor materials. In some embodiments, a carbon and fluorine containing etchant is used. For example, the carbon and fluorine containing etchant may be CₓF_{y}, such as CF₄, CHF₃, CH₃F, CH₂F₂, C₄F₈, or C₄F₆. After the anisotropic etching process, the topmost first semiconductor layer 106 and the top surface of the insulating material 118 are exposed, as shown in FIG. 7B. In other words, a portion of the fin structure 112 not covered by the sacrificial gate structure 130 and the first and second spacers 138, 139 is exposed.

As shown in FIG. 7C, the exposed portion of the fin structure 112 is recessed. In some embodiments, the first and second semiconductor layers 106, 108 of the exposed portion of the fin structure 112 are removed, and the portion of the substrate portion 116 disposed below the removed portions of the first and second semiconductor layers 106, 108 may be recessed, as shown in FIG. 7C. The recessing of the exposed portion of the fin structure 112 may be performed by a cyclic etching process. In some embodiments, each cycle of the cyclic etching process includes a plasma formation stage, an etch stage, and a purge stage. The plasma formation stage may include turning on a plasma source. The plasma source may be any suitable plasma source, such as transformer coupled plasma source, inductively coupled plasma source, capacitively coupled plasma power, or microwave coupled plasma source. In other words, a plasma power is turned on during the plasma formation stage. By turning on the plasma power, one or more gases flowing into a processing chamber are excited by the plasma power to form a plasma in the processing chamber. In some embodiments, the one or more gases include an etchant, a protection gas, and a carrier gas. For example, the etchant may be a halogen-containing gas, such as Cl₂, BCl₃, or HBr. The protection gas may be a carbon-containing gas, such as CH₄. The carrier gas may be an inert gas, such as Ar or N₂. In some embodiments, a first bias power is also turned on during the plasma formation stage. The first bias power may be applied to the semiconductor device 100 via a substrate support, such as via a first electrode embedded in the substrate support. The first bias power creates a voltage difference between the top surface of the semiconductor device structure 100 and the plasma. As a result, the distance between the top surface of the semiconductor device structure 100 and the bottom boundary of the plasma is smaller, such as from about 100 nm to about 200 nm. In some embodiments, the frequency of the first bias power is small, such as from about 0.5 MHz to about 1.5 MHz. If the frequency is greater than 1.5 MHz, the species, such as ions and radicals, in the plasma may start bombarding the semiconductor device structure 100. As a result, the etching profile may not be controlled. On the other hand, if the frequency is less than about 0.5 MHz, the plasma would be too far from the semiconductor device structure 100. As a result, the etching profile may not be controlled.

Next, at the etch stage, the plasma power and the first bias power are turned off, and a second bias power is turned on. The second bias power may be applied to the semiconductor device 100 via the substrate support, such as via a second electrode embedded in the substrate support. In some embodiments, the first and second electrodes are distinct. In some embodiments, a single electrode is utilized as the first and the second electrode, because the first and second electrodes are active at different times. In some embodiments, the frequency of the second bias power is about 13.56 MHz. The ions and radicals in the plasma are accelerated towards the semiconductor device structure 100 as a result of the second bias power. For example, the etchant, such as ions or radicals of Cl₂, BCl₃, or HBr, may etch a portion of the exposed portions of the fin structures 112 to form an opening, while the ions or radicals of the protection gas, such as CH₄, may deposit on the sidewalls of the opening. The protection gas prevents over-etching of the first and second semiconductor layers 106, 108 along the X-direction. During the etch stage, the etching process to remove a portion of the fin structure 112 by the etchant may generate a byproduct, such as SiCl₄ or SiBr₄.

In some embodiments, the plasma power remains on during the etch stage. For example, during the etch stage, the first bias power is turned off, and the plasma power and the second bias power are on.

Next, at the purge stage, the second bias power is turned off (the first bias power and the plasma power remain off), and the byproduct generated during the etching process may be purged from the processing chamber.

In some embodiments, the gases, such as the etchant, the protection gas, and the carrier gas, are flowed into the processing chamber during all three stages. In some embodiments, the flow rates of the gases may remain constant during the three stages. In some embodiments, the flow rates of the gases may be different for the three stages. For example, in some embodiments, the flow rates of the etchant and the protection gas may be slowed or stopped during the purge stage, while the flow rate of the carrier gas remains the same. The slowed or stopped flow of the etchant and the protection gas may ensure that no reaction during the purge stage, so no byproduct is generated during the purge stage. In some embodiments, the flow rate ratio of the etchant and the protection gas may be adjusted to control the loading of the first semiconductor layers 106. For example, the length along the X direction of the bottommost first semiconductor layer 106 may be substantially the same as the length of the middle first semiconductor layer 106, which may be substantially the same as the length of the topmost first semiconductor layer 106. Furthermore, in some embodiments, a greater ratio of the protection gas to the etchant may lead to longer time period of the purge stage.

The cycle of the plasma formation stage, the etch stage, and the purge stage may be repeated until the exposed portions of the first and second semiconductor layers 106, 108 not covered by the sacrificial gate structure 130 are removed. The plurality of cycles of the cyclic etching process form the source/drain (S/D) recess 143, as shown in FIG. 7C. The first and second spacers 138, 139 are recessed by the cyclic etching process, and the remaining first and second spacers 138, 139 are disposed on the insulating material 118 on opposite sides of the substrate portion 116, as shown in FIG. 7C. The protection layer 141 and a portion of the insulating material 118 may be also removed by the cyclic etching process. In some embodiments, the protection layer 141 protects the first and second spacers 138, 139 during the cyclic etching process. In other words, if the protection layer 141 is not present, the first and second spacers 138, 139 may be completely removed.

FIG. 7D is a cross-sectional side view of one of various stages of manufacturing the semiconductor device structure 100 taken along line B-B of FIG. 5, in accordance with some embodiments. FIG. 7D illustrates the semiconductor device structure 100 at the same stage as the semiconductor device structure 100 shown in FIG. 7C. As shown in FIG. 7D, the S/D recesses 143 are formed in the fin structure 112. In some embodiments, as described in FIG. 2, the opening 145 may be formed in the fin structure 112 to separate the fin structure 112 into two portions, and the insulating material 118 is formed in the opening 145. The exposed portion of the insulating material 118 not covered by the first and second spacers 138, 139 is recessed by the cyclic etching process, and the remaining insulating material 118 located in the opening 145 may have an “U” shaped cross-sectional profile, as shown in FIG. 7D. As shown in FIG. 7D, the cyclic etching process removes portions of the first and second semiconductor layers 106, 108 not covered by the sacrificial gate structures 130 and the first and second spacers 138, 139. In some embodiments, the substrate portions 116 disposed below the portions of the first and second semiconductor layers 106, 108 are also recessed by the cyclic etching process.

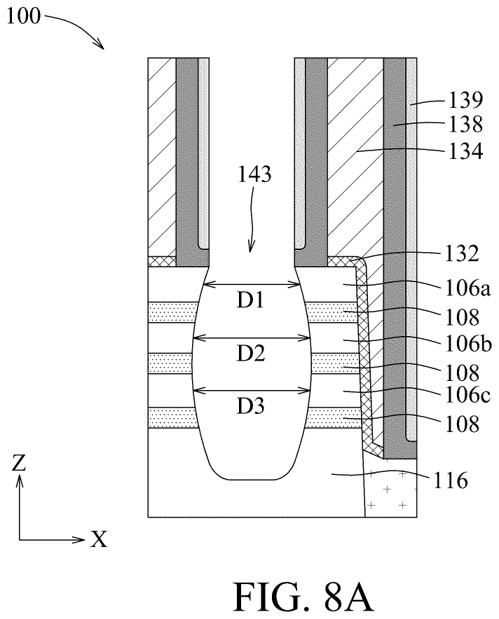

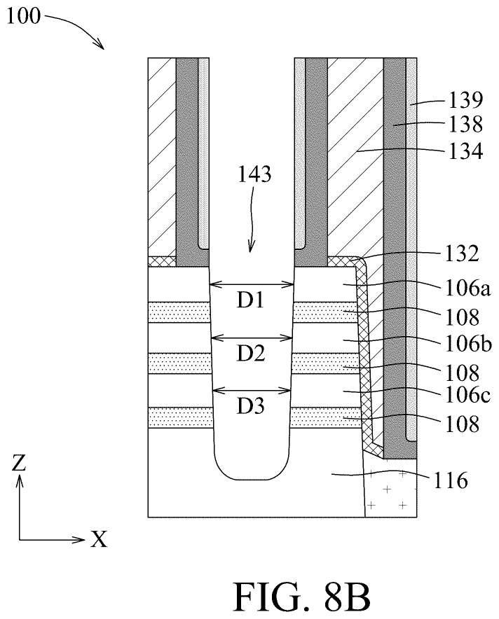

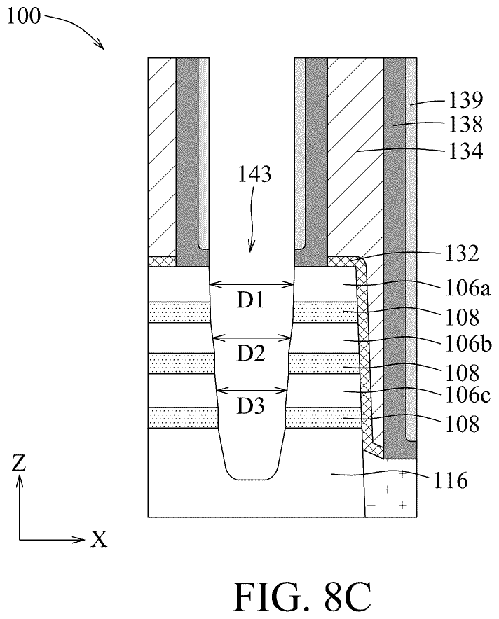

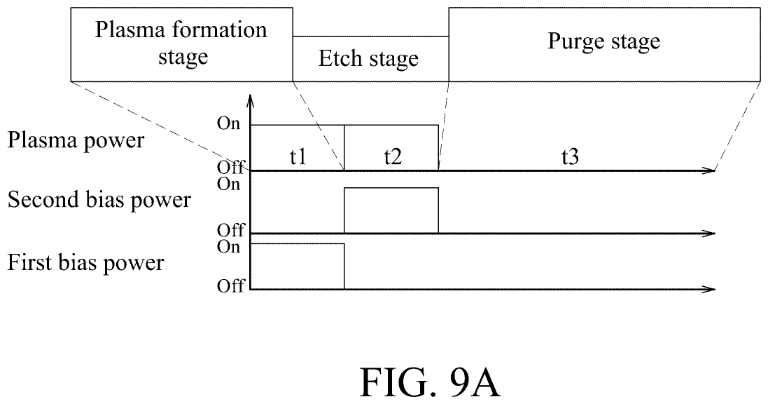

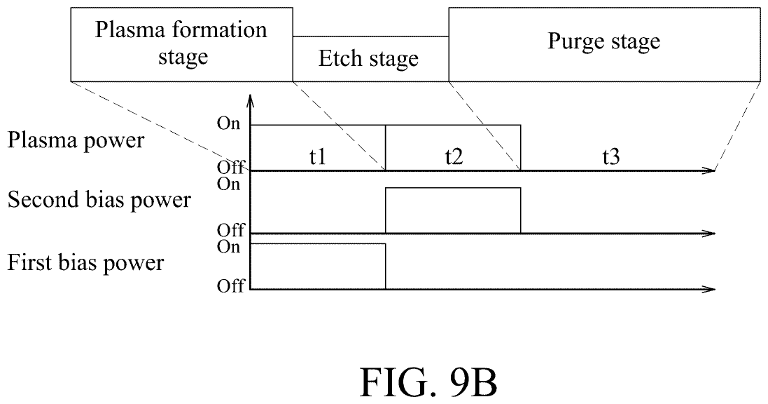

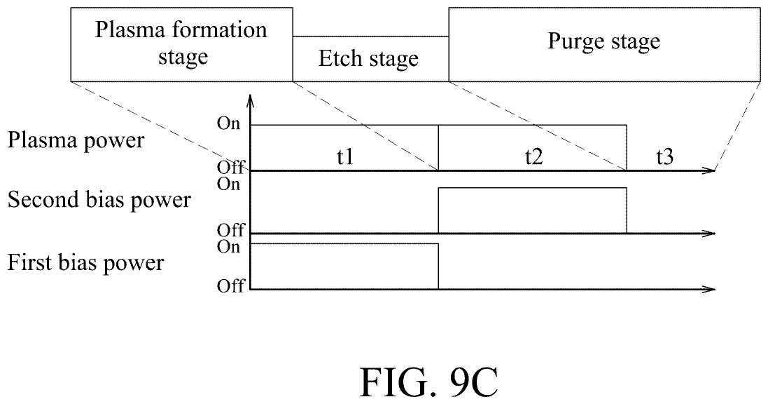

FIGS. 8A, 8B, and 8C are cross-sectional side views of a portion of the semiconductor device structure 100 of FIG. 7D, in accordance with some embodiments. In some embodiments, by adjusting the time durations of the three stages of the cyclic etching process, the shape of the S/D recesses 143 in the ZX plane may be controlled. As shown in FIGS. 8A, 8B, and 8C, the first semiconductor layers 106 includes a top first semiconductor layer 106a, a middle first semiconductor layer 106b, and a bottom first semiconductor layer 106c. A distance D1 is between adjacent top first semiconductor layers 106a, a distance D2 is between adjacent middle first semiconductor layers 106b, and a distance D3 is between adjacent bottom first semiconductor layers 106c. FIGS. 9A, 9B, and 9C are charts showing different time durations of the three stages of the cyclic etching process, in accordance with some embodiments. As shown in FIG. 9A, at the plasma formation stage, the plasma power and the first bias power are turned on for a time duration t1. At the etch stage, the plasma power and the first bias power are turned off, and the second bias power is turned on for a time duration t2. At the purge stage, the plasma power and the first bias power remain off, and the second bias power is turned off for a time duration t3. In some embodiments, as shown in FIG. 9A, the time duration t3 is greater than the time durations t1 and t2. For example, in some embodiments, the time duration t3 divided by the sum of the time durations t1 and t2 is greater than or equal to 0.5. As a result, the S/D recess 143 has a shape shown in FIG. 8A. Greater time duration t3 means longer purge time, so the side surfaces of the first and second semiconductor layers 106, 108 are less likely to be protected by the byproduct generated during the etch stage. Thus, lateral etching of the first and second semiconductor layers 106, 108 is relatively obvious, as shown in FIG. 8A. In some embodiments, the length of the top first semiconductor layer 106a along the X direction is greater than the length of the middle first semiconductor layer 106b, and the length of the bottom first semiconductor layer 106c is greater than the length of the middle first semiconductor layer 106b, as a result of the more obvious lateral etching. Similarly, the distance D1 may be less than the distance D2, and the distance D3 may be less than the distance D2. In some embodiments, the difference between the lengths of the top and middle first semiconductor layers 106a, 106b ranges from about 2.5 percent to about 16 percent. If the difference is greater than 16 percent, the length of the middle first semiconductor layer 106b may be too short. Similarly, in some embodiments, the difference between the distances D1 and D2 may range from about 2.5 percent to about 16 percent.

In some embodiments, as shown in FIG. 9B, the time duration t3 divided by the sum of the time durations t1 and t2 is between about 0.2 and about 0.5. As a result, the S/D recess 143 has a shape shown in FIG. 8B. With relatively shorter purge time compared to the chart shown in FIG. 9A, the side surfaces of the first and second semiconductor layers 106, 108 are more protected by the byproduct generated during the etch stage. Thus, lateral etching of the first and second semiconductor layers 106, 108 is less obvious, as shown in FIG. 9B. In some embodiments, the difference between the lengths of the top and middle first semiconductor layers 106a, 106b ranges from about 0 percent to about 2.5 percent, and the difference between the lengths of the top and bottom first semiconductor layers 106a, 106c ranges from about 0 percent to about 10 percent. Similarly, in some embodiments, the difference between the distances D1 and D2 may range from about 0 percent to about 2.5 percent, and the difference between the distances D1 and D3 may range from about 0 percent to about 10 percent. In some embodiments, the distances D1, D2, D3 are substantially the same.

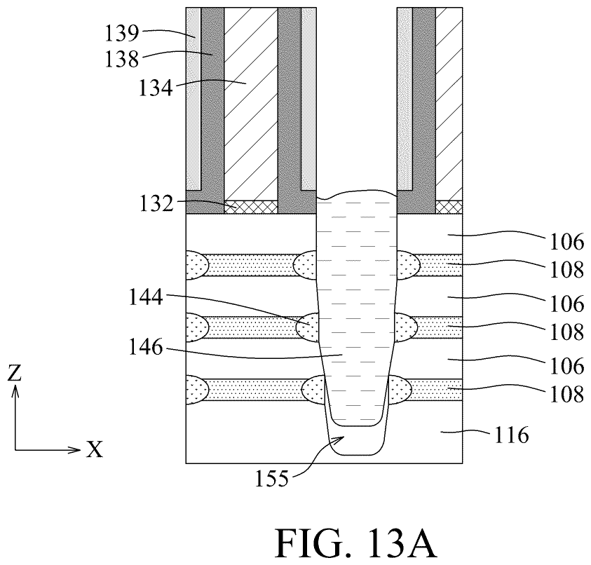

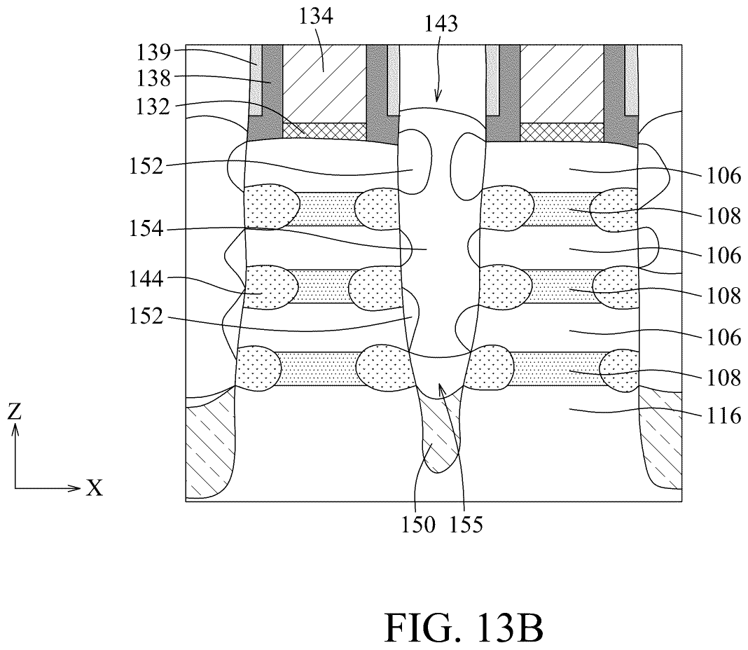

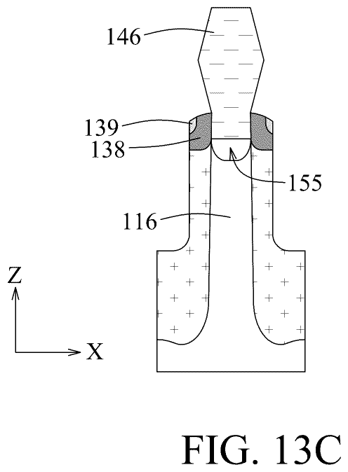

In some embodiments, as shown in FIG. 9C, the time duration t3 divided by the sum of the time durations t1 and t2 is less than or equal to about 0.2. As a result, the S/D recess 143 has a shape shown in FIG. 8C. With even shorter purge time compared to the charts shown in FIGS. 9A and 9B, the side surfaces of the first and second semiconductor layers 106, 108 are even more protected by the byproduct generated during the etch stage. Thus, lateral etching of the first and second semiconductor layers 106, 108 is even less obvious, and the S/D recess 143 is narrow, as shown in FIG. 9C. In some embodiments, the length of the top first semiconductor layer 106a is less than the length of the middle first semiconductor layer 106b, which is greater than the length of the bottom first semiconductor layer 106c, as a result of the even less lateral etching. Similarly, the distance D1 may be greater than the distance D2, which may be greater than the distance D3. In some embodiments, the difference between the lengths of the top and bottom first semiconductor layers 106a, 106c ranges from about 10 percent to about 17 percent, and the difference between the lengths of the middle and bottom first semiconductor layers 106b, 106c ranges from about 8 percent to about 15 percent. Similarly, in some embodiments, the difference between the distances D1 and D3 may range from about 10 percent to about 17 percent. With such large differences, in some embodiments, air gaps 155 (FIG. 13A) may be formed between the bottom first semiconductor layers 106c.

In some embodiments, the time durations t1, t2, and t3 are short, such as in the millisecond range, and each cycle of the cyclic etching process is also short. In some embodiments, tens of thousands of cycles are performed to form the S/D recesses 143. For example, the number of cycles of the cyclic etching process may range from about 10,000 to about 50,000. By using large number of short cycles, the shapes, or profiles, of the S/D recesses 143 may be controlled. The profiles of the S/D recesses 143 shown in FIGS. 8A, 8B, and 8C may be used in different situations to achieve different advantages.

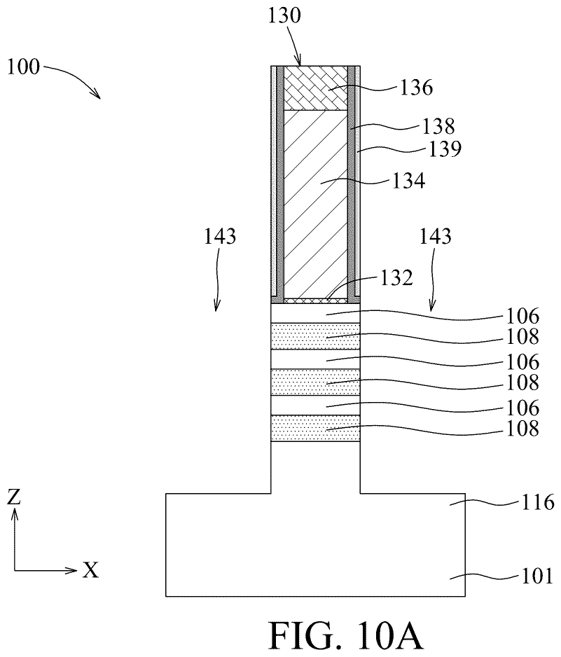

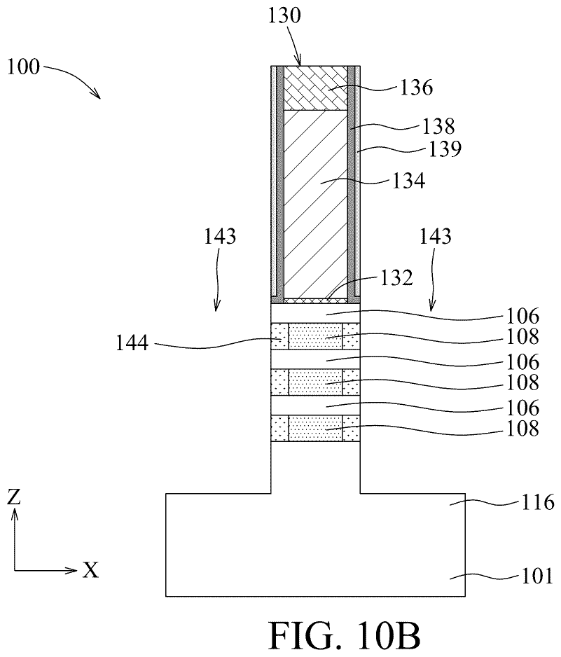

FIGS. 10A and 10B are cross-sectional side views of various stages of manufacturing the semiconductor device structure 100 taken along line A-A of FIG. 5, in accordance with some embodiments. The details of the side surfaces of the first and second semiconductor layers 106, 108 are omitted. Any of the side surfaces of the first and second semiconductor layers 106, 108 shown in FIGS. 8A, 8B, and 8C may be used in FIGS. 10A and 10B. FIG. 10A illustrates the semiconductor device structure 100 at the same manufacturing stage as the semiconductor device structure 100 shown in FIGS. 7C, 7D, 8A, 8B, or 8C. Next, as shown in FIG. 10B, edge portions of each second semiconductor layer 108 of the stack of semiconductor layers 104 are removed horizontally along the X direction, and dielectric spacers 144 are formed in the space created by the removal of edge portions of the second semiconductor layers 108. The removal of the edge portions of the second semiconductor layers 108 forms cavities. In some embodiments, the portions of the second semiconductor layers 108 are removed by a selective wet etch process. In cases where the second semiconductor layers 108 are made of SiGe and the first semiconductor layers 106 are made of silicon, the second semiconductor layer 108 can be selectively etched using a wet etchant such as, but not limited to, ammonium hydroxide (NH₄OH), tetramethylammonium hydroxide (TMAH), ethylenediamine pyrocatechol (EDP), or potassium hydroxide (KOH) solutions.

In some embodiments, instead of laterally recessing the second semiconductor layers 108, the entire second semiconductor layers 108 are removed to create openings between vertically adjacent first semiconductor layers 106. A dielectric layer (not shown) is formed in the openings between the vertically adjacent first semiconductor layers 106, and the dielectric layer is laterally recessed to form cavities.

After removing edge portions of each second semiconductor layers 108 (or the edge portions of the dielectric layer), a dielectric layer is deposited in the cavities to form the dielectric spacers 144. The dielectric spacers 144 may be made of a low-K dielectric material, such as SiON, SiCN, SiOC, SiOCN, SiO, or SiN. The dielectric spacers 144 may be formed by first forming a conformal dielectric layer using a conformal deposition process, such as ALD, followed by an anisotropic etching to remove portions of the conformal dielectric layer other than the dielectric spacers 144. The dielectric spacers 144 are protected by the first semiconductor layers 106 during the anisotropic etching process. The remaining second semiconductor layers 108 are capped between the dielectric spacers 144 along the X direction. In some embodiments, the dielectric layer is capped between the dielectric spacers 144 along the X direction.

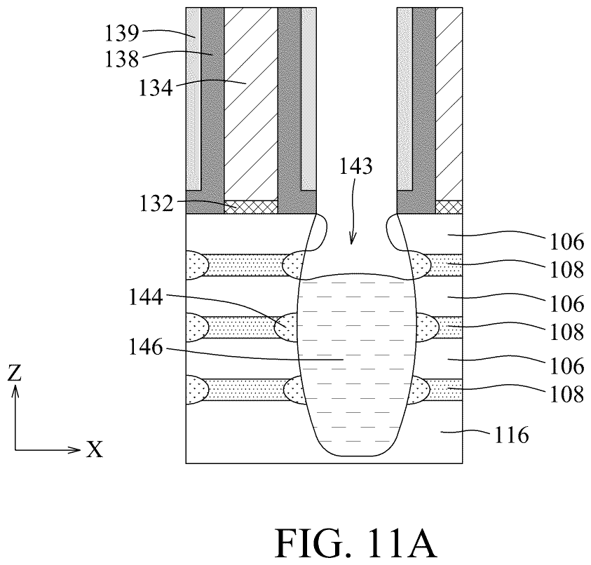

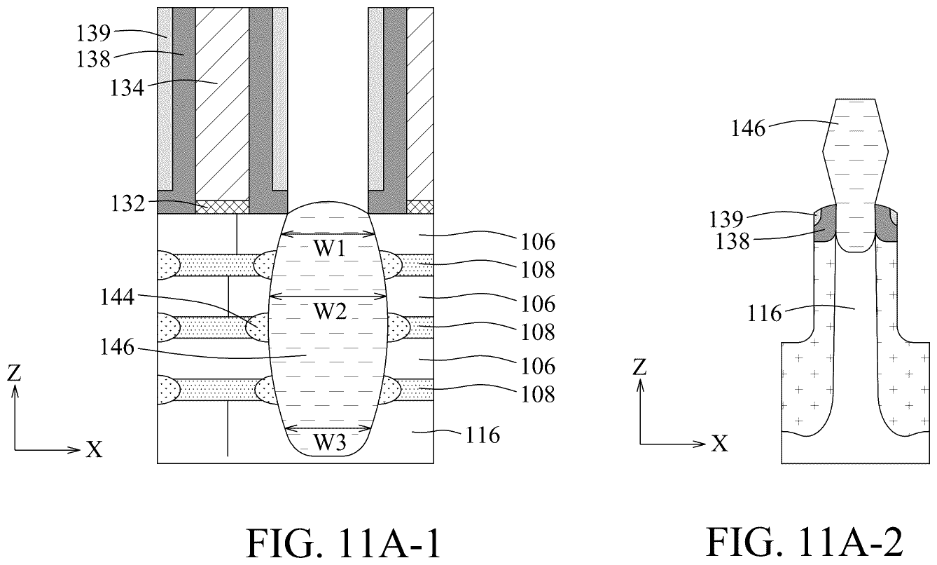

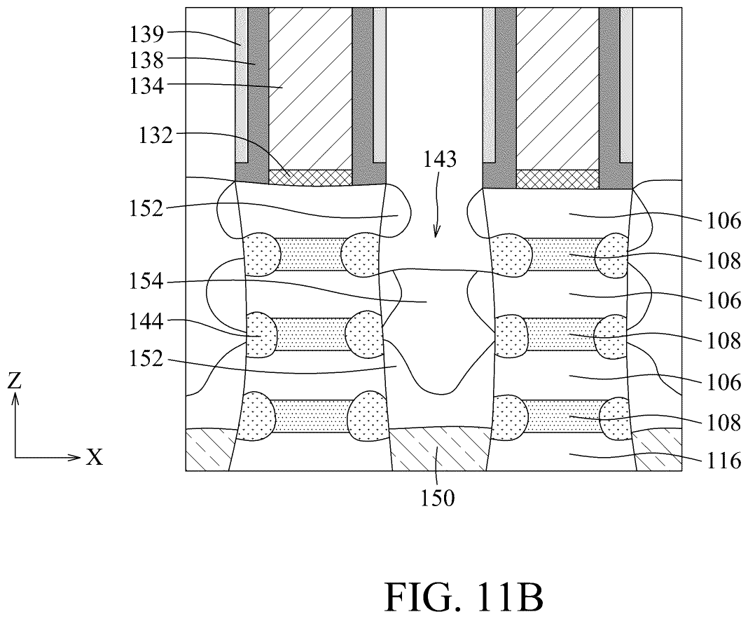

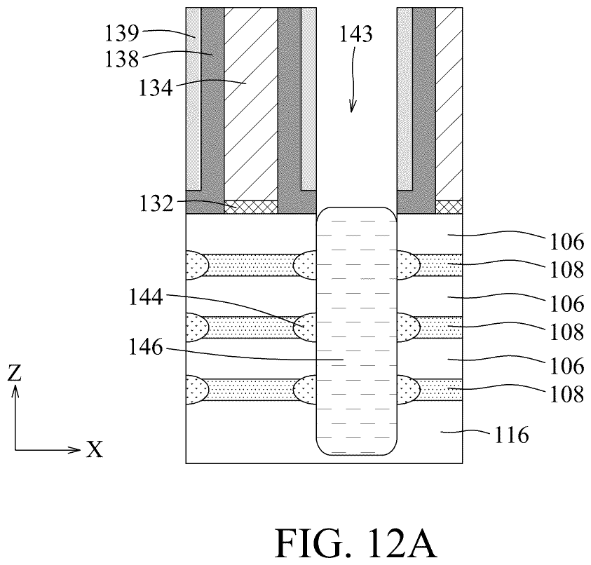

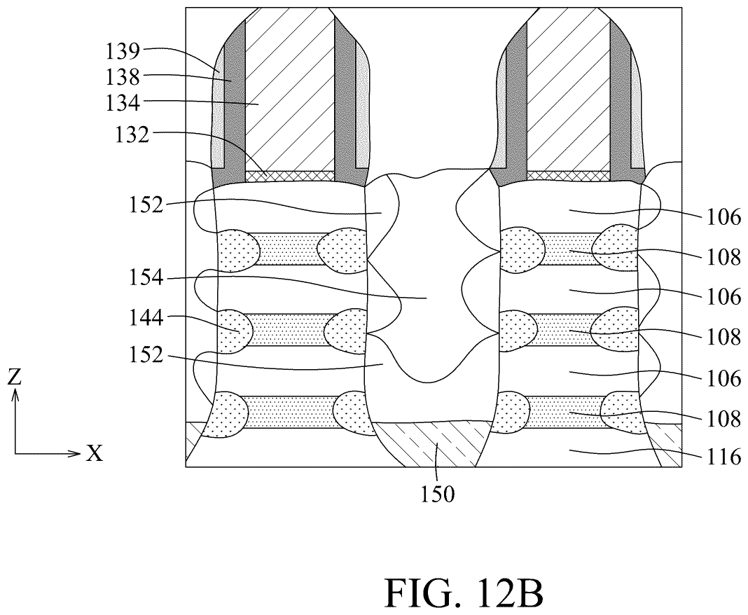

FIGS. 11A, 11B, 12A, 12B, 13A, and 13B are cross-sectional side views showing the formation of a source/drain (S/D) region 146, in accordance with some embodiments. FIGS. 11A and 11B illustrate the S/D region 146 formed in the S/D recess 143 shown in FIG. 8A, FIGS. 12A and 12B illustrate the S/D region 146 formed in the S/D recess 143 shown in FIG. 8B, and FIGS. 13A and 13B illustrate the S/D region 146 formed in the S/D recess 143 shown in FIG. 8C. In this disclosure, a source region and a drain region are interchangeably used, and the structures thereof are substantially the same. Furthermore, source/drain region(s) may refer to a source or a drain, individually or collectively dependent upon the context. In some embodiments, as shown in FIGS. 11A and 11B, due to the enlarged S/D recess 143, the S/D region 146 does not completely fill the S/D recess 143 when using a standard recipe. In some embodiments, the S/D region 146 includes multiple semiconductor layers, as shown in FIG. 11B. For example, the S/D region 146 may include a first semiconductor layer 152 and a second semiconductor layer 154. The S/D region 146 may be formed over an interposing layer 150, as shown in FIG. 11B. The interposing layer 150 may be formed on the exposed substrate portion 116. In some embodiments, the interposing layer 150 includes undoped silicon for an NMOS device or undoped SiGe for a PMOS device. The term undoped may include materials being unintentionally doped. For example, the interposing layer 150 may be undoped at the time of deposition, but may contain dopant diffused from other regions during subsequent processes. The interposing layer 150 may be first formed on semiconductor surfaces, such as on the exposed substrate portions 116 and on the first semiconductor layers 106, by epitaxy. A subsequent etch process is performed to remove the portions of the interposing layer 150 formed on the first semiconductor layers 106. In some embodiments, the interposing layer 150 is a dielectric layer, such as a SiN layer. The interposing layer 150 may be first formed in the S/D recess 143 followed by an etch back process. In some embodiments, the interposing layer 150 includes the undoped semiconductor layer, the dielectric layer, or a combination thereof. The interposing layer 150 may function as an isolation to prevent current leakage.

In some embodiments, as shown in FIG. 11A-1, the time duration for the deposition process to form the S/D region 146 is extended, so the S/D recess 143 is filled by the S/D region 146. As a result, in some embodiments, the S/D region 146 has a top portion having a width W1 along the X direction, a middle portion having a width W2, and a bottom portion having a width W3. In some embodiments, the width W2 is greater than the widths W1, W2. In some embodiments, the top portion of the S/D region 146 is located between the adjacent topmost first semiconductor layers 106, the middle portion of the S/D region 146 is located between the adjacent middle first semiconductor layers 106, and the bottom portion of the S/D region 146 is located between the adjacent substrate portions 116. In some embodiments, the bottom portion of the S/D region 146 has a curved side surface interfacing the substrate portion 116 in the XZ plane, as shown in FIG. 11A-1, and the curved side surface of the bottom portion of the S/D region 146 is substantially straight in the YZ plane due to the presence of the first and second spacers 138, 139. In some embodiments, as shown in FIG. 11A-1, the side surface of the S/D region 146 is curved, such as having a concave profile.

As shown in FIG. 11B, the first semiconductor layer 152 is formed from the first semiconductor layers 106 and the interposing layer 150. The first semiconductor layer 152 may be made of one or more layers of Si, SiP, SiC, SiAs, SiSb, and SiCP for n-channel FETs or Si, SiGe, Ge, SiGeB for p-channel FETs. For p-channel FETs, p-type dopants, such as boron (B), may be included in the first semiconductor layer 152. For n-channel FETs, n-type dopants, such as phosphorus (P) or arsenic (As), may be included in the first semiconductor layer 152. In some embodiments, the dopant concentration of the first semiconductor layer 152 may range from about 1×0¹⁹ cm⁻³ to about 2×10²¹ cm⁻³. The first semiconductor layer 152 may be formed by an epitaxial growth method using CVD, ALD or MBE. In some embodiments, the first semiconductor layer 152 is selectively formed on semiconductor materials, such as the first semiconductor layers 106 and the interposing layer 150, and is not formed on dielectric materials, such as the dielectric spacers 144. In some embodiments, the first semiconductor layer 152 includes facets, which may correspond to crystalline planes of the material used for the first semiconductor layers 106 and the interposing layer 150. In some embodiments, the first semiconductor layer 152 includes discrete portions extending from the first semiconductor layers 106 along the X direction, as shown in FIG. 11B.

As shown in FIG. 11B, the second semiconductor layer 154 is formed from the first semiconductor layer 152. The second semiconductor layer 154 may be formed by an epitaxial growth method using CVD, ALD or MBE. The second semiconductor layer 154 may be made of the same material as the first semiconductor layer 152 but with higher dopant concentration. The first semiconductor layer 152 and the second semiconductor layer 154 together may be the S/D region 146. In some embodiments, p-type S/D regions and n-type S/D regions may be formed separately using one or more mask layers.

In some embodiments, as shown in FIGS. 12A and 12B, due to less lateral etching of the first and second semiconductor layers 106, 108, the S/D region 146 completely fills the S/D recess 143. In some embodiments, the first semiconductor layers 106 are the channel region, the first semiconductor layer 152 is adjacent to the channel region, and the second semiconductor layer 154 is spaced apart from the channel region by the first semiconductor layer 152. In some embodiments, the S/D region 146 has a substantially straight side surface as a result of the shape of the S/D recess 143 (FIG. 8B), as shown in FIGS. 12A and 12B.

In some embodiments, as shown in FIG. 13A, an air gap 155 is formed below the S/D region 146. In such embodiments, the air gap 155 can function as an insulator to prevent leakage, and the S/D region 146 does not include the interposing layer 150. For example, after forming the dielectric spacers 144, the first semiconductor layer 152 is formed from the first semiconductor layers 106, and the second semiconductor layer 154 is formed from the first semiconductor layer 152. Because the distance D3 (FIG. 8C) is small, the precursor for forming the second semiconductor layer 154 may not reach to the bottom of the S/D recess 143. As a result, the air gap 155 is formed below the S/D region 146.

In some embodiments, the interposing layer 150 is formed at the bottom of the S/D recess 143, as shown in FIG. 13B. Because the processes to form the interposing layer 150 includes depositing and etching, the precursor for forming the interposing layer 150 can reach to the bottom of the S/D recess 143 to form the interposing layer 150. However, due to the small distance D3 (FIG. 8C), the precursor for the second semiconductor layer 154 may not reach the interposing layer 150. As a result, the air gap 155 is formed between the second semiconductor layer 154 and the interposing layer 150, as shown in FIG. 13B.

FIG. 13C is a cross-sectional side view of the S/D region 146 of FIG. 13A taken along line B-B of FIG. 5, in accordance with some embodiments. As shown in FIG. 13C, the air gap 155 is formed below the S/D region 146. The air gap 155 may have a height along the Z direction ranging from about 0.06 nm to about 26.3 nm. In some embodiments, the S/D region 146 has a width along the X direction and a thickness along the Z direction. The width of the S/D region 146 may be different from the thickness of the S/D region 146.

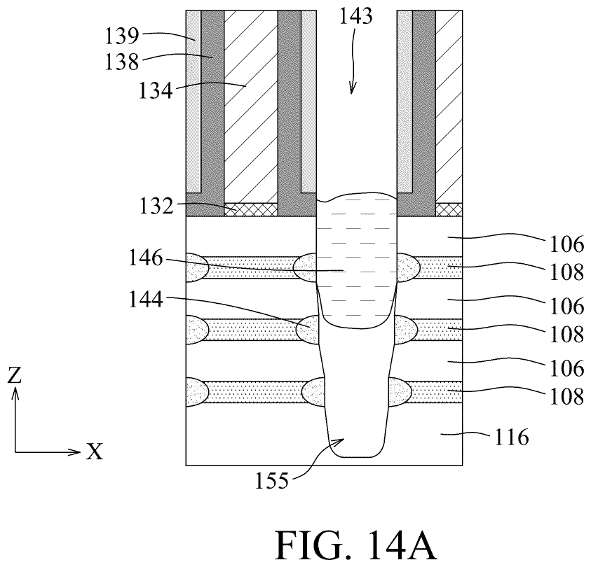

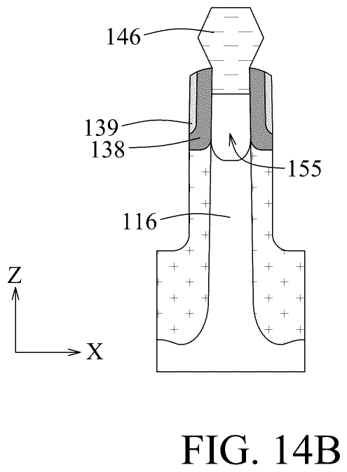

FIGS. 14A and 14B are cross-sectional side views of the S/D region 146 of FIG. 13A taken along lines B-B, A-A of FIG. 5, respectively, in accordance with alternative embodiments. As shown in FIG. 14A, in some embodiments, the distance D2 (FIG. 8C) is so small that the second semiconductor layer 154 seals the opening at a location adjacent the middle first semiconductor layers 106. As a result, the height of the air gap 155 is greater than the height of the air gap 155 shown in FIG. 13C. FIG. 14B illustrates that the height of the first and second spacers 138, 139 is also greater than the height of the first and second spacers 138, 139 shown in FIG. 13C. In some embodiments, the height of the air gap 155 is positively correlated with the height of the first and second spacers 138, 139. The height of the first and second spacers 138, 139 may be adjusted during the cyclic etching process by any suitable method.

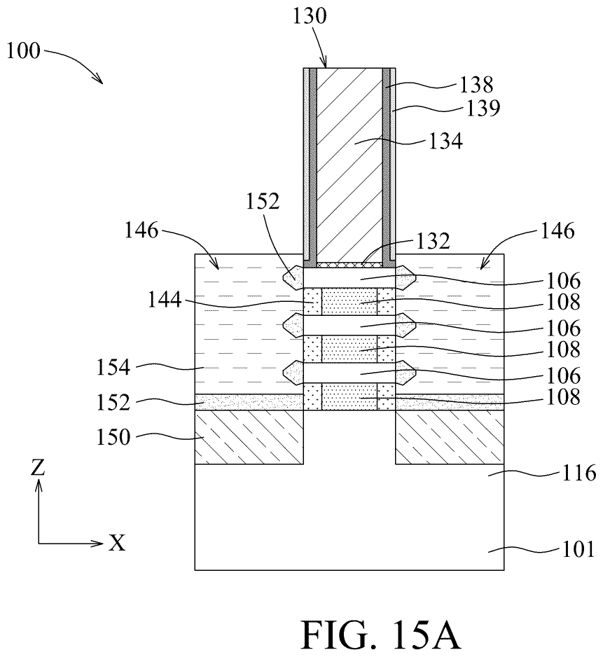

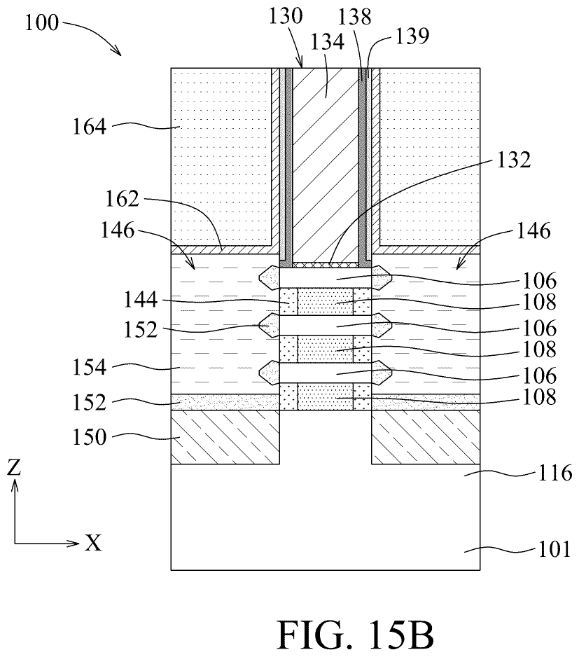

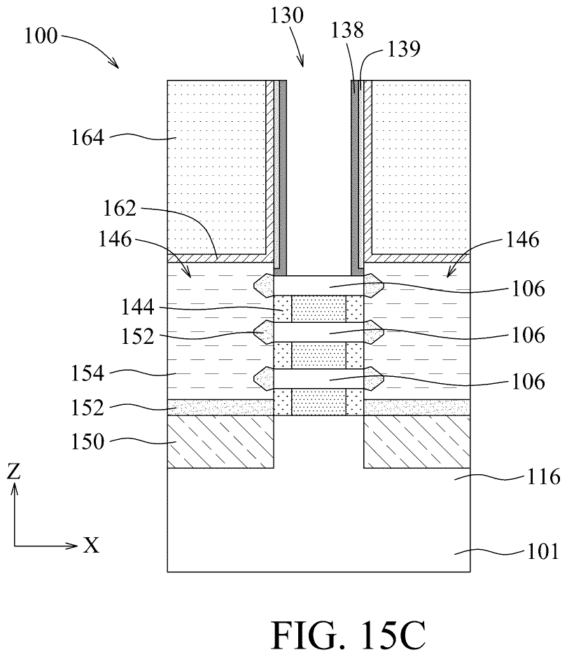

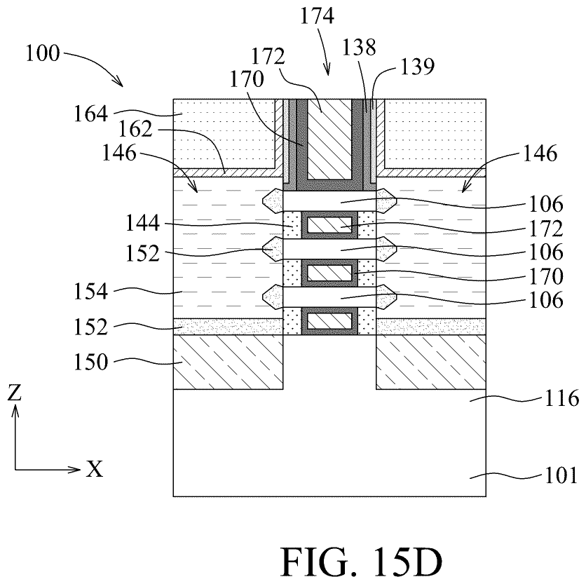

FIGS. 15A, 15B, 15C, and 15D are cross-sectional side views of various stages of manufacturing the semiconductor device structure 100 taken along line B-B of FIG. 5, in accordance with some embodiments. The shapes of the S/D regions 146 are not shown in FIGS. 15A-15D. Any of the S/D regions 146 shown in FIGS. 11A, 11B, 12A, 12B, 13A, and 13B may be used in FIGS. 15A-15D. FIG. 15A illustrates the semiconductor device structure 100 at the same manufacturing stage as the semiconductor device structure 100 shown in FIGS. 11A, 11B, 12A, 12B, 13A, and 13B. Next, as shown in FIG. 15B, a contact etch stop layer (CESL) 162 is conformally formed on the exposed surfaces of the semiconductor device structure 100. The CESL 162 covers the second spacer 139, the insulating material 118, and the S/D regions 146. The CESL 162 may include an oxygen-containing material or a nitrogen-containing material, such as silicon nitride, silicon carbon nitride, silicon oxynitride, carbon nitride, silicon oxide, silicon carbon oxide, or the like, or a combination thereof, and may be formed by CVD, PECVD, ALD, or any suitable deposition technique. In some embodiments, the CESL 162 is a single layer, as shown in FIG. 15B. In some embodiments, the CESL 162 includes two or more layers. Next, an interlayer dielectric (ILD) layer 164 is formed on the CESL 162. The materials for the ILD layer 164 may include compounds including Si, O, C, and/or H, such as silicon oxide, SiCOH, or SiOC. Organic materials, such as polymers, may also be used for the ILD layer 164. The ILD layer 164 may be deposited by a PECVD process or other suitable deposition technique. In some embodiments, after formation of the ILD layer 164, the semiconductor device structure 100 may be subject to a thermal process to anneal the ILD layer 164. In some embodiments, the CESL 162 and the ILD layer 164 are also formed on the “U” shaped insulating material 118 shown in FIG. 7D.

After the ILD layer 164 is formed, a planarization operation, such as CMP, is performed on the semiconductor device structure 100 until the sacrificial gate electrode layer 134 is exposed, as shown in FIG. 15B.

Next, as shown in FIG. 15C, the sacrificial gate structure 130 and the second semiconductor layers 108 are removed. The removal of the sacrificial gate structure 130 and the semiconductor layers 108 forms an opening between the first spacers 138 and between the first semiconductor layers 106. The ILD layer 164 protects the second semiconductor material 156 during the removal processes. The sacrificial gate structure 130 can be removed using plasma dry etching and/or wet etching. The sacrificial gate electrode layer 134 may be first removed by any suitable process, such as dry etch, wet etch, or a combination thereof, followed by the removal of the sacrificial gate dielectric layer 132, which may also be performed by any suitable process, such as dry etch, wet etch, or a combination thereof. In some embodiments, a wet etchant such as a tetramethylammonium hydroxide (TMAH) solution can be used to selectively remove the sacrificial gate electrode layer 134 but not the first spacers 138, the ILD layer 164, and the CESL 162.

The second semiconductor layers 108 may be removed using a selective wet etching process. In cases where the second semiconductor layers 108 are made of SiGe and the first semiconductor layers 106 are made of Si, the chemistry used in the selective wet etching process removes the SiGe while not substantially affecting Si, the dielectric materials of the first spacers 138, and the dielectric spacers 144. In one embodiment, the second semiconductor layers 108 can be removed using a wet etchant such as, but not limited to, hydrofluoric (HF), nitric acid (HNO₃), hydrochloric acid (HCl), or phosphoric acid (H₃PO₄).

As shown in FIG. 15D, after the formation of the nanostructure channels (i.e., the exposed portions of the first semiconductor layers 106), a gate dielectric layer 170 is formed to surround the exposed portions of the first semiconductor layers 106, and a gate electrode layer 172 is formed on the gate dielectric layer 170. The gate dielectric layer 170 and the gate electrode layer 172 may be collectively referred to as a gate structure 174. In some embodiments, an interfacial layer (IL) (not shown) is formed between the gate dielectric layer 170 and the exposed surfaces of the first semiconductor layers 106. In some embodiments, the gate dielectric layer 170 includes one or more layers of a dielectric material, such as silicon oxide, silicon nitride, or high-K dielectric material, other suitable dielectric material, and/or combinations thereof. Examples of high-K dielectric material include HfO₂, HfSiO, HfSiON, HfTaO, HfTiO, HfZrO, zirconium oxide, aluminum oxide, titanium oxide, hafnium dioxide-alumina (HfO₂—Al₂O₃) alloy, other suitable high-K dielectric materials, and/or combinations thereof. In some embodiments, the K value of the gate dielectric layer 170 is greater than the K value of the first spacer 138, the second spacer 139, or the CESL 162. The gate dielectric layer 170 may be formed by CVD, ALD or any suitable deposition technique. The gate electrode layer 172 may include one or more layers of conductive material, such as polysilicon, aluminum, copper, titanium, tantalum, tungsten, cobalt, molybdenum, tantalum nitride, nickel silicide, cobalt silicide, TiN, WN, TiAl, TiAlN, TaCN, TaC, TaSiN, metal alloys, other suitable materials, and/or any combinations thereof. The gate electrode layer 172 may be formed by CVD, ALD, electro-plating, or other suitable deposition technique. The gate electrode layer 172 may be also deposited over the ILD layer 164. The gate dielectric layer 170 and the gate electrode layer 172 formed over the ILD layer 164 are then removed by using, for example, CMP, until the top surfaces of the ILD layer 164 are exposed.

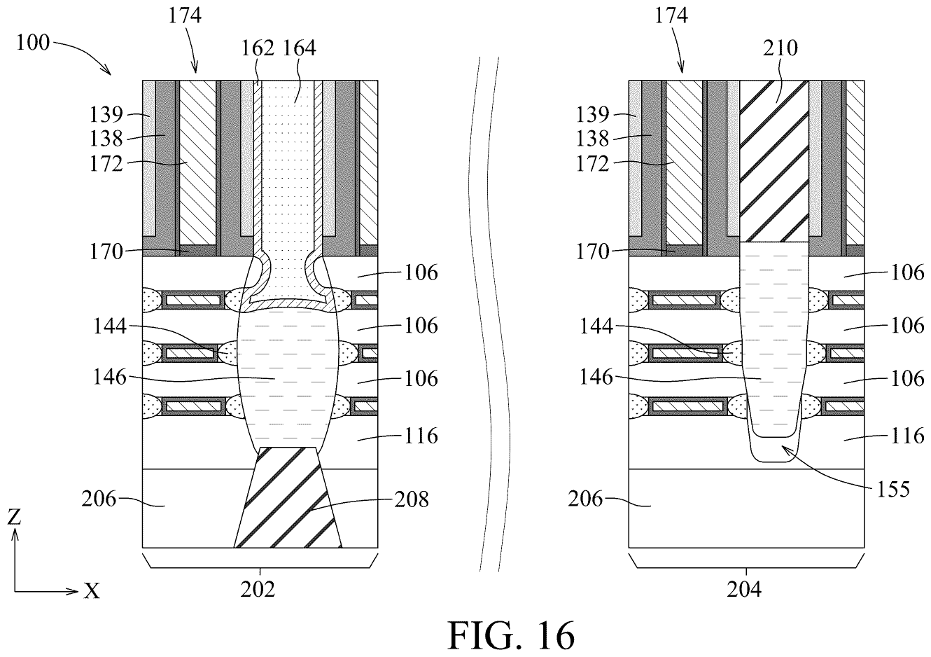

FIG. 16 is a cross-sectional side view of one of various stages of manufacturing the semiconductor device structure 100 taken along line A-A of FIG. 5, in accordance with alternative embodiments. In some embodiments, regions of the semiconductor device structure 100 in which n-type devices or p-type devices are formed are respectively referred to herein as “NMOS regions” or “PMOS regions.” As shown in FIG. 16, the semiconductor device structure 100 includes a first region 202 and a second region 204. The first region 202 may be a PMOS region or an NMOS region, and the second region 204 may be an NMOS region or a PMOS region. In some embodiments, the first region 202 is a PMOS region and the second region 204 is an NMOS region. In some embodiments, the S/D region 146 in the first region 202, i.e., PMOS region, is larger than the S/D region 146 in the second region 204, i.e., NMOS region, in order to match the electrical conductivity of the S/D regions 146 in the first and second regions 202, 204. In some embodiments, the S/D region 146 shown in FIG. 11A or 11B is used in the first region 202, while the S/D region 146 shown in FIG. 12A, 12B, 13A or 13B is used in the second region 204, because the width of the S/D region 146 along the X direction in the first region 202 is greater than the width of the S/D region 146 in the second region 204.

Furthermore, as described above, in some embodiments, the S/D region 146 in the first region 202 does not completely fill the S/D recess 143 (FIG. 11A), and the CESL and ILD layer 164 fills the S/D recess 143, as shown in FIG. 16. As a result, the conductive feature formed in the ILD layer 164 may not reach the S/D region 146 in the first region 202 due to the narrow opening. In other words, an air gap may be formed between the S/D region 146 and the conductive feature. Alternatively, the silicide layer may not be properly formed on the S/D region 146 in the first region 202. Thus, in some embodiments, a conductive feature 208 is formed on the backside of the semiconductor device structure 100 to be electrically connected to the S/D region 146 in the first region 202. A silicide layer (not shown) may be formed between the S/D region 146 and the conductive feature 208 in the first region 202. The conductive feature 208 may be formed by first flipping over the semiconductor device structure 100, so the substrate 101 is facing up. Then, a thinning process is performed to thin down the substrate 101. A dielectric layer 206 is deposited on the thinned down substrate 101, and the conductive feature 208 is formed in the dielectric layer 206. The conductive feature 208 may include any suitable electrically conductive material, such as a metal.

In the second region 204, a conductive feature 210 is formed in the ILD layer 164 to be electrically connected to the S/D region 146 from the frontside of the semiconductor device structure 100, as shown in FIG. 16. The embodiment shown in FIG. 16 may be achieved by performing the cyclic etching process described in FIG. 7C at different times for the first and second regions 202, 204. For example, in some embodiments, a mask layer is deposited in the second region 204, the cyclic etching process is performed in the first region 202, and the cyclic etching process forms the S/D recess 143 having the shape shown in FIG. 8A. Next, the S/D regions 146 are formed in the first region 202. A new mask is formed on the S/D regions 146 in the first region 202, and the mask formed in the second region 204 is removed. Next, the cyclic etching process is performed in the second region 204, and the cyclic etching process forms the S/D recess 143 having the shape shown in FIG. 8B or 8C. Then, the S/D regions 146 are formed in the second region 204.

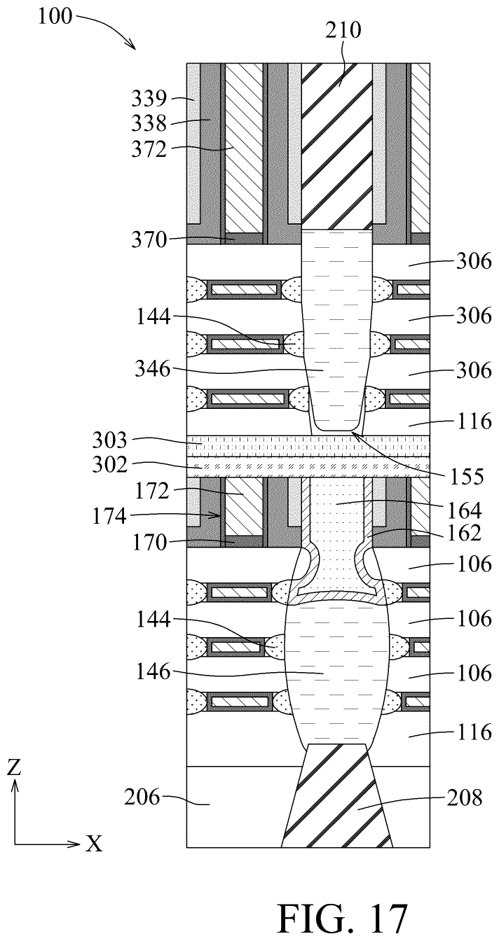

FIG. 17 is a cross-sectional side view of one of various stages of manufacturing the semiconductor device structure 100 taken along line A-A of FIG. 5, in accordance with alternative embodiments. In some embodiments, the semiconductor device structure 100 includes a complementary field effect transistor (CFET) structure, as shown in FIG. 17. In some embodiments, the S/D recesses 143 (FIGS. 8A, 8B, 8C) of the bottom transistor structure and the S/D recesses 143 of the top transistor structure are formed by different cyclic etching processes. For example, in some embodiments, the bottom transistor structure includes the PMOS region having the S/D regions 146 formed by the processes described in FIGS. 8A and 11A, and the top transistor structure includes the NMOS region having the S/D regions 146 formed by the processes described in FIGS. 8C and 13A. The CFET structure may be formed by first forming the bottom transistor structure, which is described previously. Next, a dielectric layer 302 is deposited on the gate structures 174 and the ILD layer 164. Next, a structure is bonded to the dielectric layer 302. The structure may include a substrate, a stack of semiconductor layers formed on the substrate, and a dielectric layer 303 deposited on the stack of semiconductor layers. The dielectric layers 302, 303 may be bonded using a dielectric-to-dielectric bonding process. The stack of semiconductor layers may include semiconductor layers 306 and sacrificial semiconductor layers, which may include the same material as the second semiconductor layers 108. The substrate is then removed, and a sacrificial gate structure, such as the sacrificial gate structure 130, may be formed on the stack of semiconductor layers. Next, first and second spacers 338, 339 are formed on sidewalls of the sacrificial gate structure. The first and second spacers 338, 339 may include the same material as the first and second spacers 138, 139 and may be formed by the same processes as the first and second spacers 138, 139. Then, a cyclic etching process is performed to form the S/D recesses. The purge stage of the cyclic etching process for the top transistor structure may be shorter than the purge stage of the cyclic etching process for the bottom transistor structure. As a result, the S/D recess 143 shown in FIG. 8C may be formed in the top transistor structure. Next, S/D regions 346 are formed in the S/D recesses. Next, a CESL and an ILD layer are formed over the S/D region 346, and gate electrode layers 372 and gate dielectric layers 370 are formed. The conductive feature 210 is then formed on the frontside of the CFET structure to be electrically connected to the S/D region 346, while the conductive feature 208 is formed on the backside of the CFET structure to be electrically connected to the S/D region 146.

In the CFET structure shown in FIG. 17, the bottom S/D region 146, which is in the PMOS region, is wider than the top S/D region 346, which is in the NMOS region. As a result, the electrical conductivity of the S/D regions 146, 346 in the PMOS and NMOS regions are matched. Furthermore, the air gap 155 located below the S/D region 346 prevents current leakage.

Embodiments of the present disclosure provide a semiconductor device structure and methods of forming the same. In some embodiments, the semiconductor device structure 100 includes S/D regions 146 formed in S/D recesses 143 having different shapes. The shape of the S/D recesses 143 may be controlled by adjusting the time duration of three stages of a cyclic etching process. Some embodiments may achieve advantages. For example, the different shapes of the S/D recesses 143 lead to different shapes of the S/D regions 146. By having a wider S/D region 146 in a PMOS region and a narrower S/D region 146 in an NMOS region, the electrical conductivity of the S/D regions 146 in the PMOS and NMOS regions can be matched.

An embodiment is a semiconductor device structure. The structure includes a first source/drain region located in a first region, and the first source/drain region includes a first epitaxial layer and a second epitaxial layer. The first epitaxial layer and the second epitaxial layer are doped with a dopant, a concentration of the dopant in the first epitaxial layer is different from a concentration of the dopant in the second epitaxial layer, and a thickness of the first source/drain region is different from a width of the first source/drain region in a cross-sectional view. The first source/drain region has a curved side surface. The structure further includes a first semiconductor layer disposed adjacent the first source/drain region, a second semiconductor layer disposed over the first semiconductor layer, and a gate structure disposed over the second semiconductor layer. The gate structure includes a gate dielectric layer. The structure further includes a first spacer having a first sidewall interfacing the gate dielectric layer and a second sidewall facing away from the gate structure, a contact etch stop layer (CESL) disposed facing the second sidewall of the first spacer, and a second source/drain region located in a second region. The second source/drain region has a substantially straight side surface.

Another embodiment is a semiconductor device structure. The structure includes a first source/drain region, and the first source/drain region includes a first epitaxial layer and a second epitaxial layer. The first epitaxial layer and the second epitaxial layer are doped with a dopant, a concentration of the dopant in the first epitaxial layer is different from a concentration of the dopant in the second epitaxial layer, and a thickness of the first source/drain region is different from a width of the first source/drain region in a cross-sectional view. The structure further includes a first semiconductor layer disposed adjacent the first source/drain region, a second semiconductor layer disposed over the first semiconductor layer, and a gate structure disposed over the second semiconductor layer. The gate structure includes a gate dielectric layer. The structure further includes a first spacer having a first sidewall interfacing the gate dielectric layer and a second sidewall facing away from the gate structure, a contact etch stop layer (CESL) disposed facing the second sidewall of the first spacer, and a second source/drain region disposed over the first source/drain region. An air gap is formed between the first and second source/drain regions.

A further embodiment is a method. The method includes forming a fin structure over a substrate, forming a sacrificial gate structure on a portion of the fin structure, and recessing an exposed portion of the fin structure to form a source/drain recess. The exposed portion of the fin structure is recessed by a cyclic etching process, the cyclic etching process includes performing a plurality of cycles, and each cycle includes a plasma formation stage, an etch stage, and a purge stage. A shape of the source/drain recess is controlled by adjusting a ratio of a time duration of the purge stage to a time duration of the plasma formation and etch stages.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A semiconductor device structure, comprising:
a first source/drain region located in a first region, wherein the first source/drain region comprises a first epitaxial layer and a second epitaxial layer, wherein the first epitaxial layer and the second epitaxial layer are doped with a dopant, a concentration of the dopant in the first epitaxial layer is different from a concentration of the dopant in the second epitaxial layer, and a thickness of the first source/drain region is different from a width of the first source/drain region in a cross-sectional view, and wherein the first source/drain region has a curved side surface;
a first semiconductor layer disposed adjacent the first source/drain region;
a second semiconductor layer disposed over the first semiconductor layer;
a gate structure disposed over the second semiconductor layer, wherein the gate structure comprises a gate dielectric layer;
a first spacer having a first sidewall interfacing the gate dielectric layer and a second sidewall facing away from the gate structure;
a contact etch stop layer (CESL) disposed facing the second sidewall of the first spacer; and
a second source/drain region located in a second region, wherein the second source/drain region has a substantially straight side surface.

2. The semiconductor device structure of claim 1, wherein the CESL is adjacent the second semiconductor layer.

3. The semiconductor device structure of claim 2, further comprising a third semiconductor layer disposed adjacent the second source/drain region, wherein the third semiconductor layer is located at a same level as the second semiconductor layer.

4. The semiconductor device structure of claim 1, further comprising a first conductive feature electrically connected to the first source/drain region from a backside.

5. The semiconductor device structure of claim 4, further comprising a second conductive feature electrically connected to the second source/drain region from a frontside.

6. The semiconductor device structure of claim 1, wherein a length of the second semiconductor layer is greater than a length of the first semiconductor layer.

7. The semiconductor device structure of claim 6, further comprising a fourth semiconductor layer disposed below the first semiconductor layer, wherein a length of the fourth semiconductor layer is greater than the length of the first semiconductor layer.

8. A semiconductor device structure, comprising:
a first source/drain region, wherein the first source/drain region comprises a first epitaxial layer and a second epitaxial layer, wherein the first epitaxial layer and the second epitaxial layer are doped with a dopant, a concentration of the dopant in the first epitaxial layer is different from a concentration of the dopant in the second epitaxial layer, and a thickness of the first source/drain region is different from a width of the first source/drain region in a cross-sectional view;
a first semiconductor layer disposed adjacent the first source/drain region;
a second semiconductor layer disposed over the first semiconductor layer;
a gate structure disposed over the second semiconductor layer, wherein the gate structure comprises a gate dielectric layer;
a first spacer having a first sidewall interfacing the gate dielectric layer and a second sidewall facing away from the gate structure;
a contact etch stop layer (CESL) disposed facing the second sidewall of the first spacer; and
a second source/drain region disposed over the first source/drain region, wherein an air gap is formed between the first and second source/drain regions.

9. The semiconductor device structure of claim 8, further comprising an interlayer dielectric layer disposed between the first and second source/drain regions.

10. The semiconductor device structure of claim 9, further comprising a first and a second dielectric layers disposed between the air gap and the interlayer dielectric layer.

11. The semiconductor device structure of claim 8, further comprising a third semiconductor layer disposed adjacent the second source/drain region and a fourth semiconductor layer disposed below the third semiconductor layer.

12. The semiconductor device structure of claim 11, wherein a length of the first semiconductor layer is shorter than a length of the second semiconductor layer.

13. The semiconductor device structure of claim 12, wherein a length of the fourth semiconductor layer is shorter than a length of the third semiconductor layer.

14. A method, comprising:
forming a fin structure over a substrate;
forming a sacrificial gate structure on a portion of the fin structure; and
recessing an exposed portion of the fin structure to form a source/drain recess, wherein the exposed portion of the fin structure is recessed by a cyclic etching process, the cyclic etching process comprises performing a plurality of cycles, and each cycle comprises:
a plasma formation stage;
an etch stage; and
a purge stage, wherein a shape of the source/drain recess is controlled by adjusting a ratio of a time duration of the purge stage to a time duration of the plasma formation and etch stages.

15. The method of claim 14, wherein the plasma formation stage comprises flowing an etchant, a protection gas, and a carrier gas into a processing chamber.

16. The method of claim 15, wherein flow rates of the etchant and the protection gas are reduced during the purge stage.

17. The method of claim 14, wherein the plasma formation stage comprises turning on a plasma power and a first bias power.

18. The method of claim 17, wherein the etch stage comprises turning off the first bias power and turning on a second bias power.

19. The method of claim 14, wherein the ratio is greater than or equal to 0.5 leads to lateral etching of the fin structure.

20. The method of claim 19, wherein the ratio is less than or equal to 0.2 leads to a narrow source/drain recess.
